(19) United States
(12) Patent Application Publication
(10) Pub. No.: US 2014/0085705 A1
(43) Pub. Date: Mar. 27, 2014

(54) COLOR ELECTRONIC PAPER DISPLAY AND METHOD OF FABRICATING THE SAME

(71) Applicant: Electronics and Telecommunications Research Institute, (US)

(72) Inventors: Seung Youl KANG, Daejeon (KR); Kyung Soo SUH, Daejeon (KR)

(73) Assignee: Electronics and Telecommunications Research Institute, Daejeon (KR)

(21) Appl. No.: 13/830,091

(22) Filed: Mar. 14, 2013

(30) Foreign Application Priority Data
Sep. 24, 2012 (KR) 10-2012-0105885

(51) Int. Cl. G02F 1/167; H01L 33/08

(52) U.S. Cl. CPC G02F 1/167; H01L 33/08
USPC 359/296; 438/29

(57) ABSTRACT

Provided are color electronic paper displays and methods of fabricating the same. The color electronic paper display may include a color filter provided on a lower substrate, a thin-film transistor provided between the lower substrate and the color filter, a reflection layer provided between the lower substrate and the color filter and connected to the thin-film transistor, an upper substrate provided to face the lower substrate, an upper electrode between the upper substrate and the color filter, and an electronic ink provided between the color filter and the upper electrode. The electronic ink may include monochromatic particles.

### CROSS-REFERENCE TO RELATED APPLICATIONS

This U.S. non-provisional patent application claims priority under 35 U.S.C. §119 to Korean Patent Application No. 10-2012-0105885, filed on Sep. 24, 2012, in the Korean Intellectual Property Office, the entire contents of which are hereby incorporated by reference.

### BACKGROUND OF THE INVENTION

Embodiments of the inventive concepts relate to a color electronic paper display and a method of fabricating the same.

An electronic paper is a display device having small thickness and flexibility like an ordinary paper. Further, since the electronic paper is superior in terms of visibility, flexibility, and power consumption, it is being considered one of promising next-generation displays. Due to bistability of the electronic paper, an original image can be preserved for long time even under no power condition, and this enables to reduce power consumption of the electronic paper.

Recently, in order to use the electronic paper for an electronic magazine, an electronic textbook, and an electronic advertising panel, there is a necessity to develop a novel cheap color electronic paper with excellent color gamut characteristics.

### SUMMARY

Embodiments of the inventive concepts provide a color electronic paper display with improved ink stability and a simplified method of fabricating the same.

Other example embodiments of the inventive concept provide a color electronic paper display with excellent color gamut characteristics and a method of fabricating the same.

According to example embodiments of the inventive concepts, a color electronic paper display may include a color filter provided on a lower substrate, a thin-film transistor provided between the lower substrate and the color filter, a reflection layer provided between the lower substrate and the color filter and connected to the thin-film transistor, an upper substrate provided to face the lower substrate, an upper electrode between the upper substrate and the color filter, and an electronic ink provided between the color filter and the upper electrode, the electronic ink including monochromatic particles.

In example embodiments, the thin-film transistor may include a gate electrode on the lower substrate, an active layer disposed adjacent to the gate electrode, a gate insulating layer between the gate electrode and the active layer, and a source electrode and a drain electrode provided at both sides of the active layer. The reflection layer extends from the drain electrode between the lower substrate and the color filter.

In example embodiments, the reflection layer may be a metal-containing layer and be provided in a form of plate.

In example embodiments, the display may further include a black matrix provided on the lower substrate to cover the thin-film transistor.

In example embodiments, the electronic ink may further include transparent dielectric fluid.

In example embodiments, the monochromatic particles may be formed to represent one of white, black, or monochromatic colors.

In example embodiments, the electronic ink may be provided in a microcapsule.

In example embodiments, the display may further include a lower electrode provided between the lower substrate and the upper electrode and on the color filter, and an insulating pattern between the upper electrode and the lower electrode. The insulating pattern may be formed to define first openings exposing a portion of a top surface of the lower electrode.

In example embodiments, lower widths of the first openings may be less than upper widths of the first openings.

In example embodiments, the display may further include a spacer interposed between the upper electrode and the insulating pattern to provide a region, through which the electronic ink can be supplied.

In example embodiments, the upper electrode may be a transparent electrode.

In example embodiments, the color filter may include second openings exposing a portion of a top surface of the reflection layer.

In example embodiments, lower widths of the second openings may be less than upper widths of the second openings.

According to example embodiments of the inventive concepts, a method of fabricating a color electronic paper display may include forming a color filter on a lower substrate, and forming a thin-film transistor between the lower substrate and the color filter. The forming of the thin-film transistor may include forming a gate electrode on the lower substrate, forming an active layer adjacent to the gate electrode, forming a gate insulating layer between the gate electrode and the active layer, and forming a source electrode and a drain electrode at both sides of the active layer. The drain electrode may be formed to extend between the color filter and the lower substrate and have a length greater than that of the source electrode.

In example embodiments, the method may further include forming a lower electrode on the color filter, and forming an insulating pattern on the lower electrode. The forming of the insulating pattern may include depositing an insulating layer on the lower electrode, and etching a portion of the insulating layer to expose a portion of a top surface of the lower electrode.

In example embodiments, the method may further include providing an upper substrate to face the lower substrate, forming an upper electrode between the upper substrate and the lower electrode, and supplying an electronic ink between the lower electrode and the upper electrode. The electronic ink may include monochromatic particles.

In example embodiments, the electronic ink may further include a transparent dielectric fluid, and the electronic ink may be contained in a microcapsule and may be provided between the lower and upper electrodes.

In example embodiments, the forming of the color filter may include etching a portion of the color filter to expose partially a top surface of the extending portion of the drain electrode.

### BRIEF DESCRIPTION OF THE DRAWINGS

Example embodiments will be more clearly understood from the following brief description taken in conjunction with the accompanying drawings. FIGS. 1 through 16 represent non-limiting, example embodiments as described herein.

FIG. 1 is a plan view of a color electronic paper display according to a first embodiment of the inventive concept.

FIG. 2 is a cross-sectional view taken along a line I-I′ of FIG. 1.

FIGS. 3 and 4 are provided to explain a coloring principle of the color electronic paper display according to the first embodiment of the inventive concept, and are cross-sectional views taken along a line I-I′ of FIG. 1.

FIG. 5 is a plan view of a color electronic paper display according to a second embodiment of the inventive concept.

FIG. 6 is a cross-sectional view taken along a line II-II′ of FIG. 5.

FIGS. 7 and 8 are provided to explain a coloring principle of the color electronic paper display according to the second embodiment of the inventive concept, and are cross-sectional views taken along a line II-II′ of FIG. 5.

FIG. 9 is a plan view of a color electronic paper display according to the third embodiment of the inventive concept.

FIG. 10 is a cross-sectional view taken along a line III-III′ of FIG. 9.

FIGS. 11 and 12 are provided to explain a coloring principle of the color electronic paper display according to the third embodiment of the inventive concept, and are cross-sectional views taken along a line III-III′ of FIG. 9.

FIGS. 13 through 16 are provided to describe a method of fabricating a color electronic paper according to the first embodiment of the inventive concept, and are cross-sectional views taken along a line I-I′ of FIG. 1.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

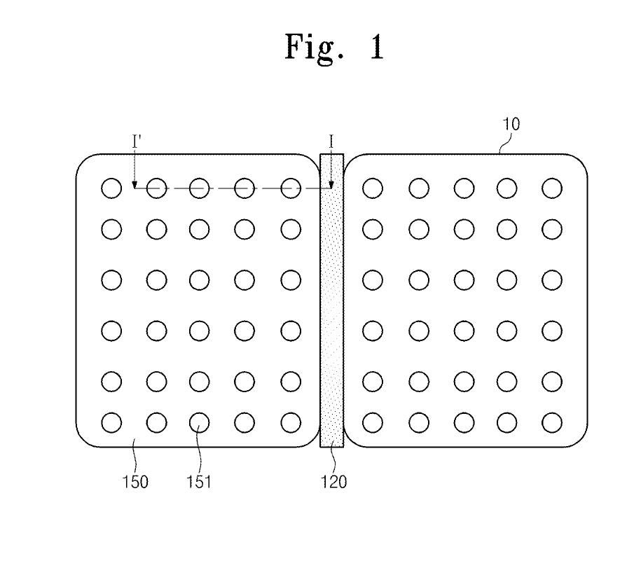

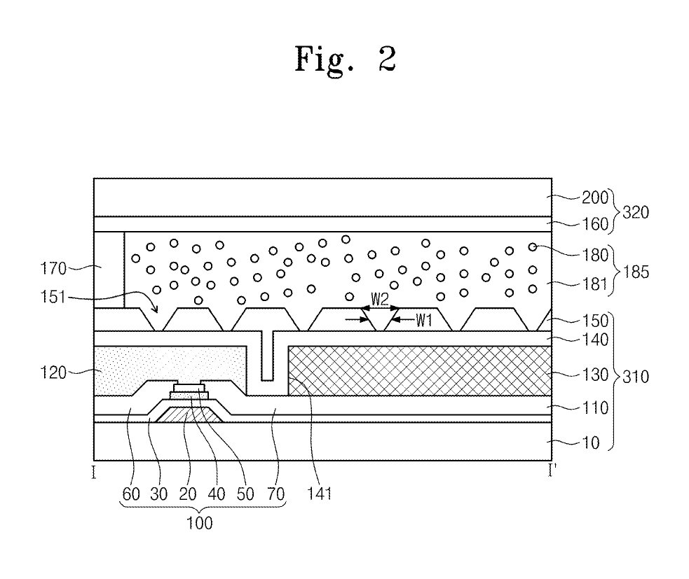

FIG. 1 is a plan view of a color electronic paper display according to a first embodiment of the inventive concept, and FIG. 2 is a sectional view taken along a line I-I′ of FIG. 1.

Referring to FIGS. 1 and 2, according to the first embodiment of the inventive concept, a color electronic paper display may include a lower array substrate 310, an upper array substrate 320 on the lower array substrate 310, an electronic ink 185 injected between the lower array substrate 310 and the upper array substrate 320, and a spacer 170 interposed between the lower array substrate 310 and the upper array substrate 320. The spacer 170 may be configured to form a gap, through which the electronic ink 185 can be injected or supplied.

The lower array substrate 310 may include a lower substrate 10, a lower electrode 140 on the lower substrate 10, a thin-film transistor 100 between the lower substrate 10 and the lower electrode 140, a color filter 130 interposed between the lower substrate 10 and the lower electrode 140 to be adjacent to the thin-film transistor 100, a reflection layer 110 provided between the lower substrate 10 and the color filter 130 to be coupled to the thin-film transistor 100, a black matrix 120 interposed between the lower substrate 10 and the lower electrode 140 to cover the thin-film transistor 100, and an insulating pattern 150 on the lower electrode 140.

The lower substrate 10 may be formed of a flexible material. For example, the lower substrate 10 may be formed of a glass film, a plastic film, or a semiconductor substrate.

The thin-film transistor 100 may include a gate electrode 20 applied with a gate voltage, an active layer 40 disposed adjacent to the gate electrode 20, a gate insulating layer 30 between the gate electrode 20 and the active layer 40, and a source electrode 60 and a drain electrode 70 spaced apart from each other with the active layer 40 interposed therebetween. The active layer 40 may be configured to form a channel region between the source electrode 60 and the drain electrode 70. The thin-film transistor 100 may further include a protection layer 50 provided on the active layer 40 to protect the active layer 40 against an unintended etching damage. For example, as shown in FIG. 2, the thin-film transistor may be a bottom-gate type, in which the gate electrode 20 is provided below the active layer 40, or a top-gate type, in which the gate electrode 20 is provided on the active layer 40. The gate electrode 20 and the source/drain electrodes 60 and 70 may contain a conductive metal. For example, the gate insulating layer 30 may be a silicon oxide layer or a silicon nitride layer. The active layer 40 may include an amorphous silicon layer, and the protection layer 50 may include an insulating layer, such as an aluminum oxide layer (AlOx), a silicon nitride layer (SiNx), and/or a silicon oxide layer (SiOx).

The reflection layer 110 may extend from the thin-film transistor 100. For example, the reflection layer 110 may be a portion of the drain electrode 70, which has a plate-shaped structure extending between the color filter 130 and the lower substrate 10. The reflection layer 110 may include a highly reflective metal layer. For example, the reflection layer 110 may include a metal layer (e.g., of Al or Ti).

The black matrix 120 may be provided between the lower substrate 10 and the lower electrode 140 to cover the thin-film transistor 100. The black matrix 120 may be used to separate pixels of the color electronic paper display from each other. For example, the black matrix 120 may be a negative photoresist layer provided with a dark dye. The color filter 130 may be located on the reflection layer 110. For example, the color filter 130 may be configured to have substantially the same technical features as that in a conventional LCD device or in a CYM color filter displaying C (cyan), M (magenta), and Y (yellow). Although not shown, a protection layer may be located on the color filter 130 to prevent the color filter 130 from being deteriorated.

The lower electrode 140 may be disposed on the black matrix 120 and the color filter 130. The lower electrode 140 may be electrically connected to the drain electrode 70. For example, the color filter 130 may be etched to form a contact hole 141 exposing the drain electrode 70, and the lower electrode 140 may be connected to the drain electrode 70 through the contact hole 141. The lower electrode 140 may be a transparent electrode (e.g., indium tin oxide (ITO) or indium zinc oxide (IZO)). Accordingly, particles in the electronic ink 185 can be controlled or operated by the lower electrode 140 and a light from the color filter 130 can pass through the lower electrode 140.

The insulating pattern 150 may be disposed on the lower electrode 140. The insulating pattern 150 may include first openings 151 exposing a portion of a top surface of the lower electrode 140. Lower widths w1 of the first openings 151 may be less than upper widths w2 of the first openings 151. For example, the first openings 151 may have a funnel-shaped structure having width getting narrower from top to bottom. The insulating pattern 150 may include an organic layer or an inorganic layer (e.g., a silicon oxide layer).

The upper array substrate 320 may include an upper substrate 200 and an upper electrode 160 between the upper substrate 200 and the lower array substrate 310. The upper substrate 200 may be disposed to face the lower substrate 10. The upper substrate 200 may include a transparent and flexible material. For example, the upper substrate 200 may be formed of a glass film, a plastic film, or a semiconductor substrate. The upper electrode 160 may be disposed on the upper substrate 200, such that an electric field may be generated between the lower electrode 140 and the upper electrode 160. The upper electrode 160 may be a transparent electrode (e.g., indium tin oxide (ITO) or indium zinc oxide (IZO)).

The spacer 170 may be provided between the upper array substrate 320 and the lower array substrate 310. Due to the presence of the spacer 170, the upper array substrate 320 and the lower array substrate 310 may be spaced apart from each other by a uniform space without damage thereof, when they are jointed to each other. The spacer 170 may be configured to provide an electronic ink injection region between the upper electrode 160 and the lower electrode 140. The spacer 170 may include an elastic material. For example, the spacer 170 may include an organic layer (e.g., acrylic resin and so forth) contained with a black pigment.

The electronic ink 185 may be injected between the lower array substrate 310 and the upper array substrate 320. The electronic ink 185 may include a transparent dielectric fluid 181 and monochromatic particles 180 distributed in the transparent dielectric fluid 181. The monochromatic particles 180 may be formed to represent one of white, black, or monochromatic colors. In this case, dispersibility of the electronic ink can be maintained with ease, compared with the cases of using heterogeneous particles (for example, white and black particles) or colored dielectric fluid. This enables to improve stability of ink and simplify a fabrication process.

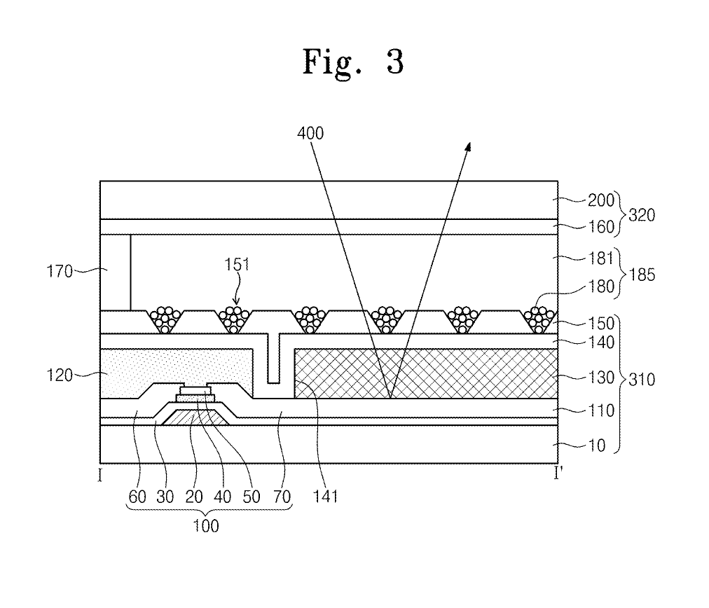

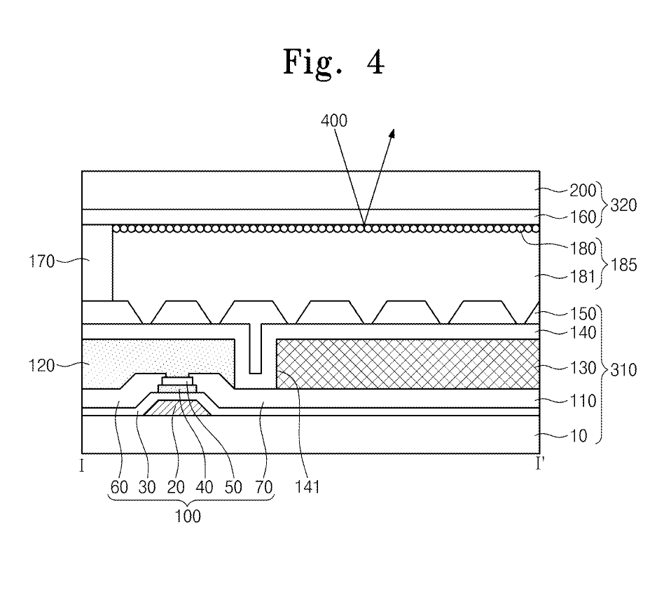

FIGS. 3 and 4 are provided to explain a coloring principle of the color electronic paper display according to the first embodiment of the inventive concept, and are sectional views taken along a line I-I′ of FIG. 1.

The thin-film transistor 100 may be operated to apply a voltage to the lower electrode 140, in such a way that a potential difference is produced between the upper electrode 160 and the lower electrode 140. For example, the thin-film transistor 100 may be operated in such a way that a positive or negative voltage are applied to the electrodes 140 and 160, respectively. The monochromatic particles 180 in the electronic ink 185 may have a predetermined polarity, and thus, the monochromatic particles 180 may be moved toward the upper electrode 160 or the lower electrode 140 by the potential difference. For example, as shown in FIG. 3, if the upper electrode 160 and the lower electrode 140 are applied with negative and positive voltages, respectively, the negatively charged monochromatic particles 180 may be moved toward the lower electrode 140 and be localized in the first openings 151 of the insulating pattern 150. Accordingly, an external light 400 incident through the upper array substrate 320 may pass through the color filter 130 and be reflected by the reflection layer 110, such that each pixel region can display color of its color filter 130. As shown in FIG. 4, if the upper electrode 160 and the lower electrode 140 are applied with positive and negative voltages, respectively, the negatively charged monochromatic particles 180 may be moved toward the upper electrode 160 and be distributed below the upper electrode 160. Accordingly, an external light 400 incident through the upper array substrate 320 may be reflected by the monochromatic particles 180, and each pixel region can display color of the monochromatic particles 180. For example, if the monochromatic particles 180 are white particles, the pixel region may display white.

According to example embodiments of the inventive concept, the reflection layer 110 may include a highly reflective metal layer (e.g., with reflectance of 95% or more). This enables to increase color gamut or color-expression property of the device.

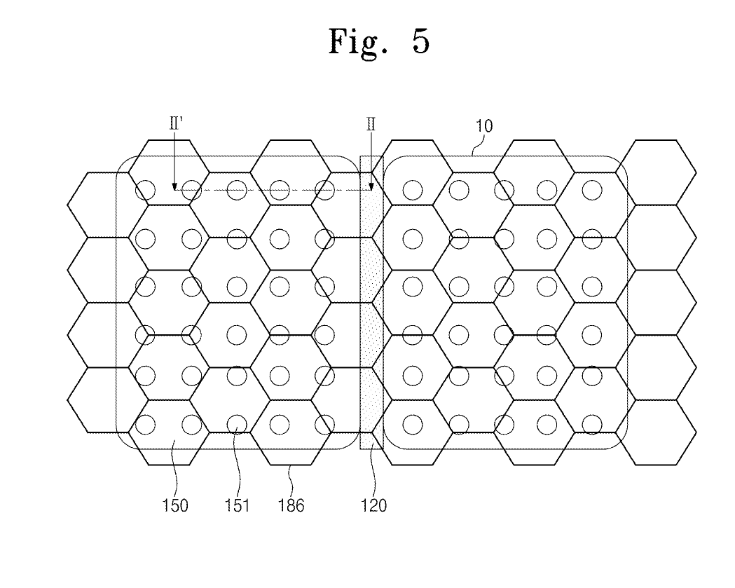

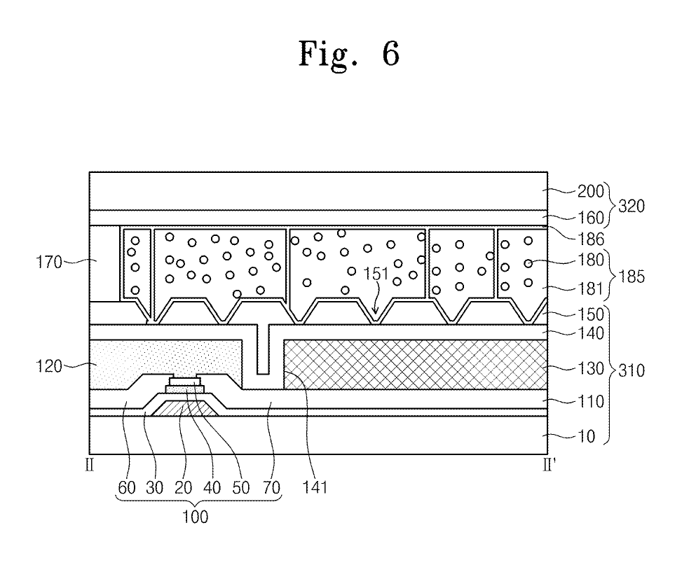

FIG. 5 is a plan view of a color electronic paper display according to a second embodiment of the inventive concept, and FIG. 6 is a cross-sectional view taken along a line II-IF of FIG. 5. For the sake of brevity, the elements and features of this example that are similar to those previously shown and described will not be described in much further detail.

Referring to FIGS. 5 and 6, according to the second embodiment of the inventive concept, a color electronic paper display may include microcapsules 186 that are injected between the lower array substrate 310 and the upper array substrate 320. The electronic ink 185 may be provided in the microcapsules 186. The electronic ink 185 may include the transparent dielectric fluid 181 and the monochromatic particles 180 dispersed in the transparent dielectric fluid 181. The microcapsules 186 may be formed of a polymer material. For example, the polymer material may be at least one of natural polymers (such as, gelatin, arabic gum, or sodium alginate), semi-synthetic polymers (such as, carboxyl methyl cellulose or ethyl cellulose), or synthetic polymers (such as, polyvinyl alcohol, nylon, polyurethane, polyester, epoxy, melamine-formalin). The microcapsules 186 may be provided on the insulating pattern 150 with the first openings 151. Each of the microcapsules 186 may be in contact with at least one of the first openings 151 of the insulating pattern 150. Since the polymer material can be easily deformed by an external structure, a lower portion of the microcapsules 186 may have a similar profile to the insulating pattern 150. Accordingly, the monochromatic particles 180 in the microcapsules 186 may be moved toward the first openings 151 of the insulating pattern 150.

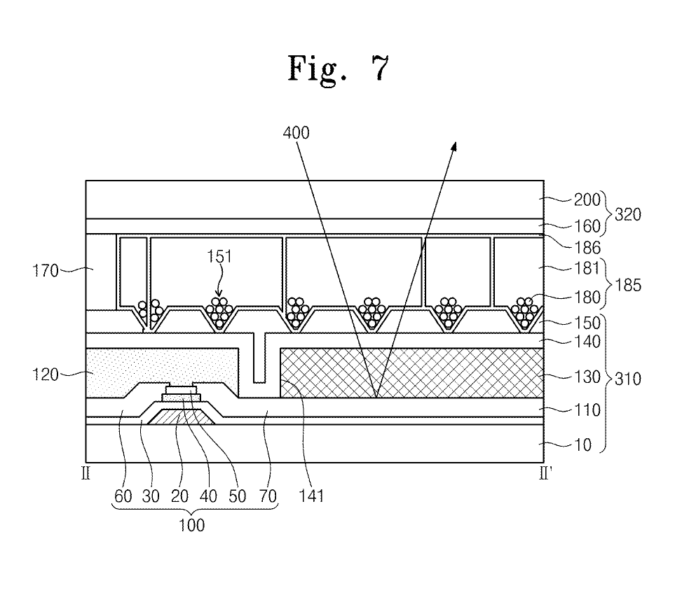

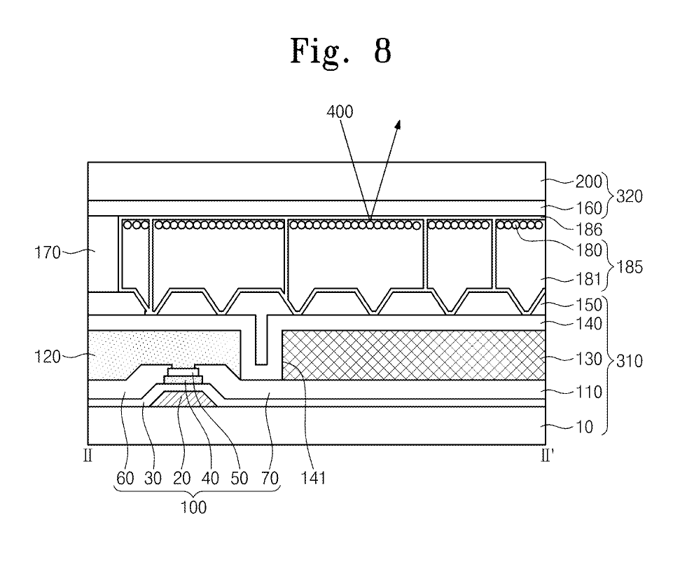

FIGS. 7 and 8 are cross-sectional views illustrating a coloring principle of the color electronic paper display according to the second embodiment of the inventive concept. For the sake of brevity, the elements and features of this example that are similar to those previously shown and described will not be described in much further detail.

As described above, the thin-film transistor 100 may be operated to apply a voltage to the lower electrode 140, in such a way that a potential difference is produced between the upper electrode 160 and the lower electrode 140. The monochromatic particles 180 may be moved toward the upper electrode 160 or the lower electrode 140 by the potential difference. For example, as shown in FIG. 7, if the upper electrode 160 and the lower electrode 140 are applied with negative and positive voltages, respectively, the negatively charged monochromatic particles 180 may be moved toward the lower electrode 140 and be localized in the first openings 151 of the insulating pattern 150. Accordingly, an external light 400 incident through the upper array substrate 320 may pass through the color filter 130 and be reflected by the reflection layer 110, such that each pixel region can display color of its color filter 130. As shown in FIG. 8, if the upper electrode 160 and the lower electrode 140 are applied with positive and negative voltages, respectively, the negatively charged monochromatic particles 180 may be moved toward the upper electrode 160 and be distributed below the upper electrode 160. Accordingly, an external light 400 incident through the upper array substrate 320 may be reflected by the monochromatic particles 180, and each pixel region can display color of the monochromatic particles 180. For example, if the monochromatic particles 180 are white particles, the pixel region may display white.

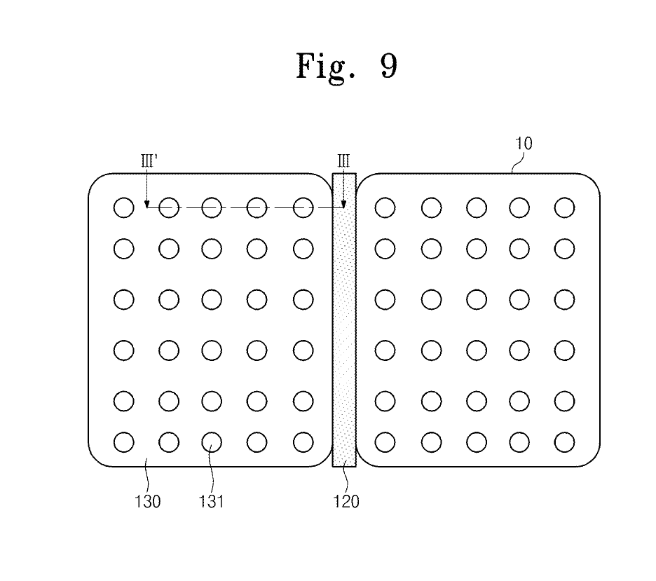

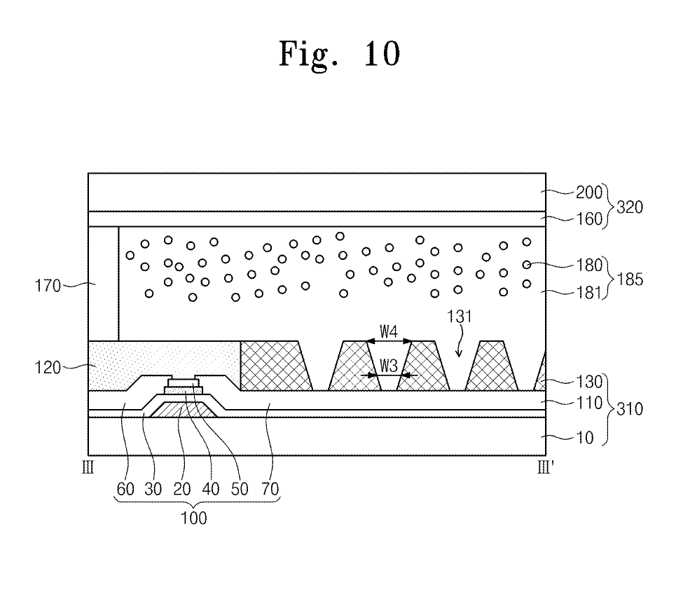

FIG. 9 is a plan view of a color electronic paper display according to a third embodiment of the inventive concept, and FIG. 10 is a cross-sectional view taken along a line III-III′ of FIG. 9. For the sake of brevity, the elements and features of this example that are similar to those previously shown and described will not be described in much further detail.

Referring to FIGS. 9 and 10, according to the third embodiment of the inventive concept, a color electronic paper display may include the color filter 130 defining second openings 131. The color filter 130 may be disposed on the reflection layer 110, and the color filter 130 may include the second openings 131 exposing a portion of the top surface of the reflection layer 110. Lower widths w3 of the second openings 131 may be less than upper widths w4 of the second openings 131. For example, the second openings 131 may have a funnel-shaped structure having width getting narrower from top to bottom. In the case where the color filter 130 has the second openings 131, the color electronic paper display may be configured not to have the lower electrode 140 and the insulating pattern 150, unlike that described with reference to FIGS. 1 through 4. In this case, the reflection layer 110 may serve as the lower electrode of the structure described with reference to FIGS. 1 through 4.

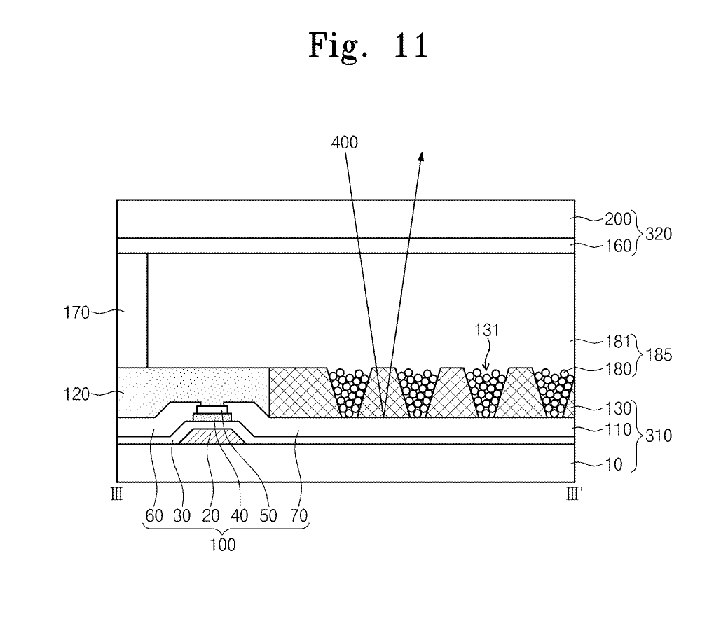

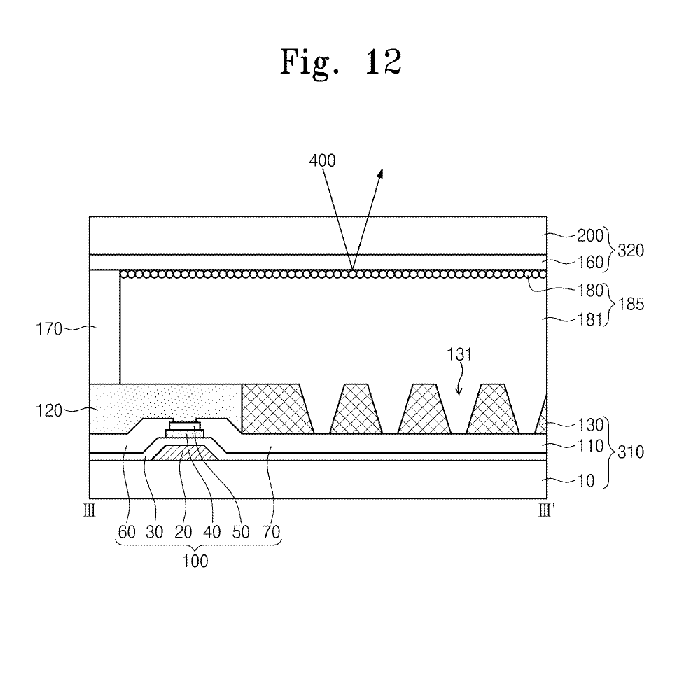

FIGS. 11 and 12 are cross-sectional views illustrating a coloring principle of the color electronic paper display according to the third embodiment of the inventive concept. For the sake of brevity, the elements and features of this example that are similar to those previously shown and described will not be described in much further detail.

According to the third embodiment of the inventive concept, in the case where the color filter 130 has the second openings 131, the reflection layer 110 provided below the color filter 130 may serve as the lower electrode. Accordingly, the thin-film transistor 100 may be operated to apply a voltage to the reflection layer 110, in such a way that a potential difference is produced between the upper electrode 160 and the reflection layer 110. The monochromatic particles 180 may be moved toward the upper electrode 160 or the reflection layer 110 by the potential difference. For example, as shown in FIG. 11, if the upper electrode 160 and the reflection layer 110 are applied with negative and positive voltages, respectively, the negatively charged monochromatic particles 180 may be moved toward the reflection layer 110 and be localized in the second openings 131 of the color filter 130. Accordingly, an external light 400 incident through the upper array substrate 320 may pass through the color filter 130 and be reflected by the reflection layer 110, such that each pixel region can display color of its color filter 130. As shown in FIG. 12, if the upper electrode 160 and the reflection layer 110 are applied with positive and negative voltages, respectively, the negatively charged monochromatic particles 180 may be moved toward the upper electrode 160 and be distributed below the upper electrode 160. Accordingly, an external light 400 incident through the upper array substrate 320 may be reflected by the monochromatic particles 180, and each pixel region can display color of the monochromatic particles 180. For example, if the monochromatic particles 180 are white particles, the pixel region may display white.

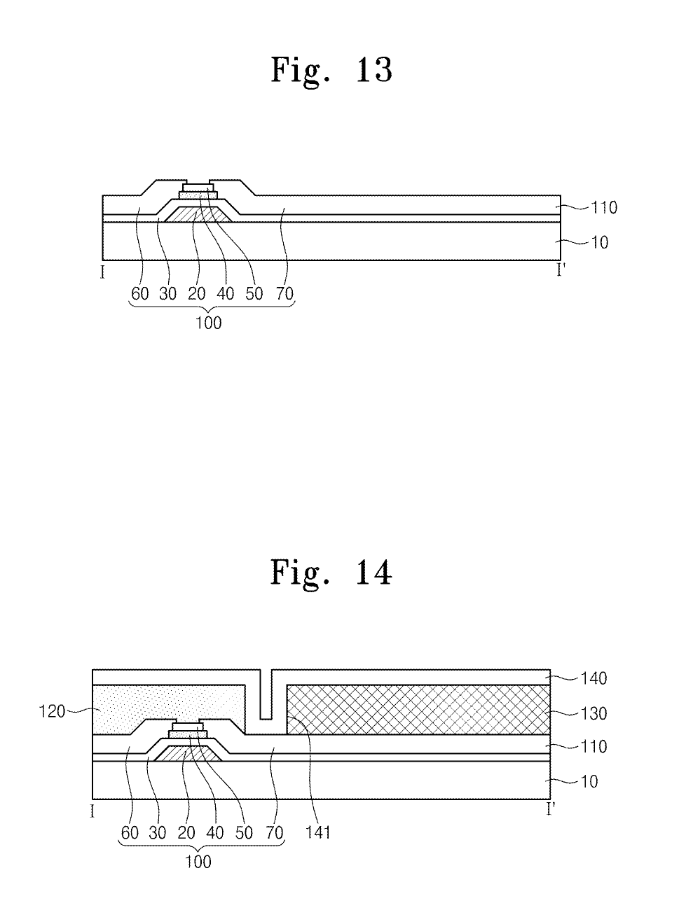

FIGS. 13 through 16 are sectional views illustrating a method of fabricating a color electronic paper according to the first embodiment of the inventive concept.

Referring to FIG. 13, a first conductive layer may be formed on the lower substrate 10 by a deposition process (e.g., a sputtering process) and be patterned to form the gate electrode 20. In example embodiments, the first conductive layer may include a conductive metal layer (e.g., of molybdenum (Mo), chromium (Cr), aluminum (Al), or copper (Cu). The gate insulating layer 30 may be formed on the lower substrate 10 provided with the gate electrode 20. In example embodiments, the gate insulating layer 30 may be formed by a deposition process (e.g., PECVD or sputtering process). The gate insulating layer 30 may be formed of, for example, a silicon oxide layer or a silicon nitride layer. An insulating layer (e.g., an amorphous silicon layer and a silicon oxide layer) may be formed on the gate insulating layer 30 by performing a deposition process (e.g., PECVD or sputtering process), and then, the insulating layer may be patterned to form the active layer 40 and the protection layer 50 provided on the active layer 40. Thereafter, a second conductive layer may be formed on the lower substrate 10 by performing a deposition process (e.g., PECVD or sputtering process). The second conductive layer may include, for example, a conductive metal layer (e.g., of molybdenum (Mo), chromium (Cr), or aluminum (Al)). Thereafter, the second conductive layer may be patterned to form the source and drain electrodes 60 and 70. In this case, a portion of the drain electrode 70 may extend parallel to the top surface of the lower substrate 10, such that the drain electrode 70 may have a length greater than that of the source electrode 60. The extending portion of the drain electrode 70 may be used for the reflection layer 110. In other words, as the result of the process of patterning the second conductive layer, the thin-film transistor 100 may be formed to include the gate electrode 20, the gate insulating layer 30, the active layer 40, the protection layer 50, the source and drain electrodes 60 and 70, and the reflection layer 110 extending from the drain electrode 70.

Referring to FIG. 14, the black matrix 120 may be formed to cover the thin-film transistor 100. In example embodiments, a negative photoresist provided with a black dye may be coated on the lower substrate 10 by a spin-coating method. The negative photoresist provided with the black dye may be exposed by an ultraviolet light and be developed to form the black matrix 120 having a patterned structure. The color filter 130 may be formed adjacent to the black matrix 120. The color filter 130 may be formed on the reflection layer 110 and be configured to display a predetermined color. Although not shown, a protection layer may be additionally formed on the color filter 130 to prevent the color filter 130 from being deteriorated.

The lower electrode 140 may be formed on the black matrix 120 and the color filter 130. For example, the color filter 130 may be patterned by a photolithography process and/or an etching process to form the contact hole 141 exposing the drain electrode 70. A transparent conductive material may be deposited on the contact hole 141, the black matrix 120, and the color filter 130 and be patterned to form the lower electrode 140 connected to the drain electrode 70. The transparent conductive material may be an indium tin oxide (ITO) layer or an indium zinc oxide (IZO) layer. In other embodiments, the color filter 130 may be patterned to form the second openings 131 exposing a portion of the top surface of the reflection layer 110. In this case, steps of forming the lower electrode 140 and the insulating pattern 150 to be described below may be omitted.

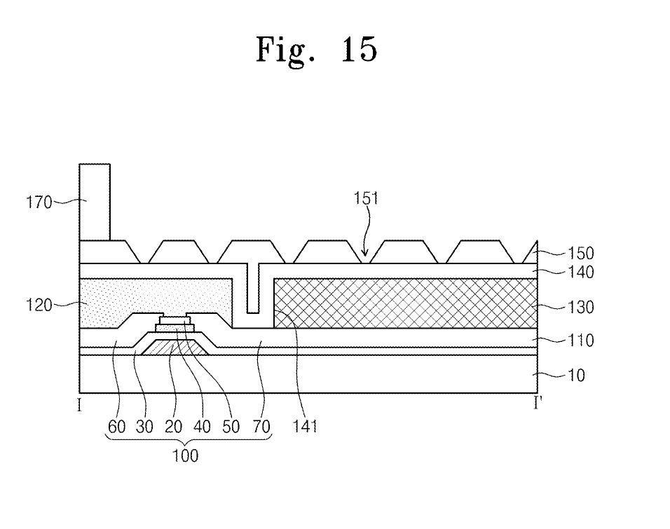

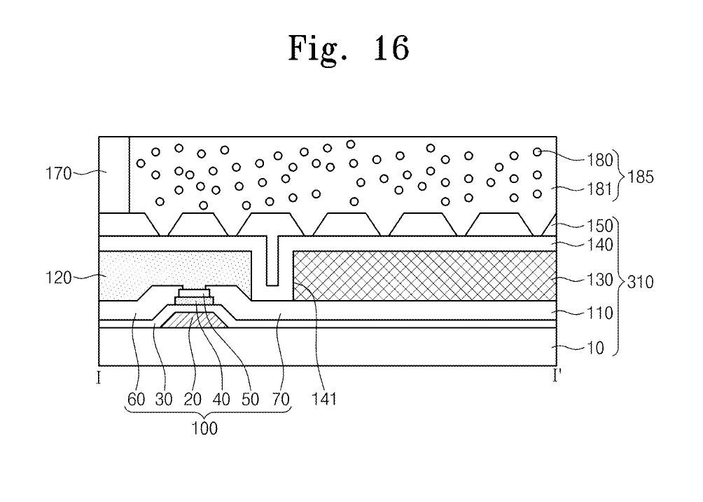

Referring to FIG. 15, the insulating pattern 150 may be formed on the lower electrode 140. For example, an insulating layer may be formed on the lower electrode 140 by performing a film-forming process (e.g., a spin coating or PECVD process). The insulating layer may be an organic layer or an inorganic layer (e.g., a silicon oxide layer). An etching process or an imprint process may be further performed to the insulating layer to form the insulating pattern 150. The insulating pattern 150 may be formed to define the first openings 151 exposing a portion of the top surface of the lower electrode 140. The spacer 170 may be formed on the insulating pattern 150. For example, an organic layer (e.g., acrylic resin) may be coated on the insulating pattern 150. The organic layer may be patterned using at least one of a photo lithography process, an imprint process, or a screen-printing process, thereby forming the spacer 170.

Referring to FIG. 16, the electronic ink 185 may be provided on the lower array substrate 310, which is the resulting structure of the process described with reference to FIGS. 13 through 15. The spacer 170 may provide a region, through which the electronic ink 185 can be supplied or injected. The electronic ink 185 may include the transparent dielectric fluid 181 and the monochromatic particles 180 dispersed in the transparent dielectric fluid 181. In example embodiments, the electronic ink 185 may be injected after the formation of the lower array substrate 310 and the spacer 170, and the upper array substrate 320 to be described below may be formed thereon. In other embodiments, after the formation of the lower array substrate 310, the spacer 170, and the upper array substrate 320, the electronic ink 185 may be injected between the lower and upper array substrates 310 and 320. In still other embodiments, the electronic ink 185 may be provided by disposing an ink-containing microcapsule, as previously described with reference to FIGS. 5 and 6.

Referring back to FIG. 2, the upper array substrate 320 including the upper electrode 160 and the upper substrate 200 may be provided on the lower array substrate 310. The upper electrode 160 may be formed on the entire top surface of the upper substrate 200, and include a transparent conductive material (e.g., indium tin oxide (ITO) or indium zinc oxide (IZO)). The upper substrate 200 may include a transparent and flexible material. For example, the upper substrate 200 may be a glass, a plastic film, or a semiconductor substrate.

According to example embodiments of the inventive concept, an electronic ink provided with monochromatic particles may be used for a color electronic paper display. This enables to improve stability of ink and simplify a process of fabricating the color electronic paper display. In addition, a reflection layer provided below a color filter may be used to display image, and this enables to realize a color electronic paper display with improved color gamut characteristics.

While example embodiments of the inventive concepts have been particularly shown and described, it will be understood by one of ordinary skill in the art that variations in form and detail may be made therein without departing from the spirit and scope of the attached claims.

What is claimed is:

1. A color electronic paper display, comprising:
a color filter provided on a lower substrate;
a thin-film transistor provided between the lower substrate and the color filter;
a reflection layer provided between the lower substrate and the color filter and connected to the thin-film transistor;
an upper substrate provided to face the lower substrate;
an upper electrode between the upper substrate and the color filter; and
an electronic ink provided between the color filter and the upper electrode, the electronic ink comprising monochromatic particles.

2. The color electronic paper display of claim 1, wherein the thin-film transistor comprises:
a gate electrode on the lower substrate;
an active layer disposed adjacent to the gate electrode;
a gate insulating layer between the gate electrode and the active layer; and
a source electrode and a drain electrode provided at both sides of the active layer,
wherein the reflection layer extends from the drain electrode between the lower substrate and the color filter.

3. The color electronic paper display of claim 2, wherein the reflection layer is a metal-containing layer.

4. The color electronic paper display of claim 2, wherein the reflection layer is provided in a form of plate.

5. The color electronic paper display of claim 1, further comprising, a black matrix provided on the lower substrate to cover the thin-film transistor.

6. The color electronic paper display of claim 1, wherein the electronic ink further comprises transparent dielectric fluid.

7. The color electronic paper display of claim 6, wherein the monochromatic particles are formed to represent one of white, black, or monochromatic colors.

8. The color electronic paper display of claim 6, wherein the electronic ink is provided in a microcapsule.

9. The color electronic paper display of claim 1, further comprising:
a lower electrode provided between the lower substrate and the upper electrode and on the color filter; and
an insulating pattern between the upper electrode and the lower electrode,
wherein the insulating pattern is formed to define first openings exposing a portion of a top surface of the lower electrode.

10. The color electronic paper display of claim 9, wherein lower widths of the first openings are less than upper widths of the first openings.

11. The color electronic paper display of claim 9, further comprising a spacer interposed between the upper electrode and the insulating pattern to provide a region, through which the electronic ink can be supplied.

12. The color electronic paper display of claim 1, wherein the upper electrode is a transparent electrode.

13. The color electronic paper display of claim 1, wherein the color filter comprises second openings exposing a portion of a top surface of the reflection layer.

14. The color electronic paper display of claim 13, wherein lower widths of the second openings are less than upper widths of the second openings.

15. A method of fabricating a color electronic paper display, comprising:
forming a color filter on a lower substrate; and
forming a thin-film transistor between the lower substrate and the color filter,
wherein the forming of the thin-film transistor comprises:
forming a gate electrode on the lower substrate;
forming an active layer adjacent to the gate electrode;
forming a gate insulating layer between the gate electrode and the active layer; and
forming a source electrode and a drain electrode at both sides of the active layer,
wherein the drain electrode is formed to extend between the color filter and the lower substrate and have a length greater than that of the source electrode.

16. The method of claim 15, further comprising:
forming a lower electrode on the color filter; and
forming an insulating pattern on the lower electrode,
wherein the forming of the insulating pattern comprises:
depositing an insulating layer on the lower electrode; and
etching a portion of the insulating layer to expose a portion of a top surface of the lower electrode.

17. The method of claim 16, further comprising,
providing an upper substrate to face the lower substrate;
forming an upper electrode between the upper substrate and the lower electrode; and
supplying an electronic ink between the lower electrode and the upper electrode,
wherein the electronic ink comprises monochromatic particles.

18. The method of claim 17, wherein the electronic ink further comprises a transparent dielectric fluid, and
the electronic ink is contained in a microcapsule and is provided between the lower and upper electrodes.

19. The method of claim 15, wherein the forming of the color filter comprises etching a portion of the color filter to expose partially a top surface of the extending portion of the drain electrode.
